(19) United States
(12) Patent Application Publication
(10) Pub. No.: US 2013/0207646 A1
(43) Pub. Date: Aug. 15, 2013

(54) MAGNETIC SENSOR APPARATUS

(71) Applicant: Xiao-Qiao KONG, Lian Yun Gang (CN)

(72) Inventor: Xiao-Qiao KONG, Lian Yun Gang (CN)

(21) Appl. No.: 13/370,266

(22) Filed: Feb. 9, 2012

(51) Int. Cl. G01R 35/00

(52) U.S. Cl. 324/202

(57) ABSTRACT

A magnetic sensor apparatus includes a substrate, a plurality of magnetoresistance sensor units, a reset coil and a compensation coil. The magnetoresistance sensor units are disposed on the substrate. The reset coil is disposed over the magnetoresistance sensor units for introducing a resetting current, and a magnetic field generated from this resetting current can be used to reset magnetization directions of the magnetoresistance sensor units. The reset coil includes a plurality of first main segments. The compensation coil is disposed over the magnetoresistance sensor units for introducing a compensating current, and another magnetic field generated from the compensating current is used as a compensation magnetic field onto the magnetoresistance sensor units. The compensation coil includes a plurality of second main segments. The first main segments of the reset coil are perpendicular to the second main segments of the compensation coil.

### BACKGROUND

1. Field of Invention

The present invention relates to a magnetic sensor apparatus. More particularly, the present invention relates to a design of coil structures within a magnetic sensor apparatus.

2. Description of Related Art

The resistance of a magnetoresistance material will change in response to the variation of an external magnetic field. This is referred to as the magnetoresistance effect. Based on the magnetoresistance effect, magnetoresistance material can be utilized in some applications requiring sensors operating in response to a magnetic force or magnetic field, e.g., compassing applications, metal detection applications or positioning applications.

Giant magnetoresistance (GMR) magnetic sensors and anisotropic magnetoresistance (AMR) magnetic sensors are two main types of magnetic sensor applications utilizing magnetoresistance material.

A giant magnetoresistance effect exists between multiple layers of ferromagnetic materials (e.g., Fe, Co and Ni) and non-ferromagnetic materials (e.g., Cr, Cu, Ag and Au). The multiple layers within giant magnetoresistance magnetic sensors are formed by stacking the ferromagnetic and non-ferromagnetic materials alternately. Therefore, complex procedures are involved in manufacturing giant magnetoresistance magnetic sensors.

An anisotropic magnetoresistance effect exists in bulk-portions or films with a ferromagnetic material (e.g., Fe, Co and Ni) or an alloy of such a ferromagnetic material. A resistive variation of an anisotropic magnetoresistance sensor is related to an operating current flowing through an anisotropic magnetoresistance material of the sensor.

Each magnetoresistance material within a magnetoresistance sensor may have a magnetization direction. The magnetization directions of all the magnetoresistance materials will change in response to magnetic fields from the surrounding environment. Therefore, the initial magnetization directions of the magnetoresistance materials can be different under different environmental conditions.

In addition, differences in temperature may also cause a sensitivity shift in the magnetic sensing of a magnetoresistance sensor. The sensing outcomes generated by the magnetoresistance sensor under high temperature and low temperature conditions may be different when other conditions are left unchanged. Therefore, temperature may lead to a distortion in the sensing outcomes generated by a magnetoresistance sensor.

The distortion caused by temperature can be calibrated by a compensation coil. For example, magnetic fields in two opposite directions are established by a specific coil onto the magnetoresistance sensor, and then sensing outcomes under the magnetic fields in two opposite direction are compared for generating a compensation parameter. The compensation coil is used to calibrate the distortion caused by temperature according to the compensation parameter. However, only a half of segments on a traditional compensation coil are used for establishing a compensation magnetic field in the same direction, because the traditional compensation coil is usually formed in a singular spiral shape. The area efficiency of the traditional compensation coil is about 50%. Therefore, considerable space (especially the width of the space) is required for the traditional compensation coil.

In other words, traditional magnetoresistance sensors face problems including the inconsistency of internal magnetization directions and the sensing distortion caused by temperature.

### SUMMARY

In order to solve the aforesaid problem, this disclosure provides a magnetic sensor apparatus including a plurality of magnetoresistance sensor units, a compensation coil and a reset coil. The compensation coil is used for introducing a compensation current for establishing a compensation magnetic field that is used for calibrating the magnetic sensitivity of the magnetoresistance sensor units which may be changed due to different temperatures. The reset coil is used for introducing a resetting current for establishing a resetting magnetic field, so as to reset the magnetization directions of the magnetoresistance sensor units to the same direction at the beginning of the magnetic sensing process. Furthermore, the distortion due to different temperatures can be calibrated according to a comparison result between two sensing outcomes generated under two reset magnetic fields in opposite directions. In other words, the current value of the compensation current can be determined by aforesaid comparison result between two sensing outcomes corresponding to two reset magnetic fields in opposite directions. The main segments of the reset coil and the main segment of the compensation coil are perpendicular to each others, and the reset coil and the compensation coil are used for establishing two magnetic fields for different purposes.

An aspect of the invention is to provide a magnetic sensor apparatus including a substrate, a plurality of magnetoresistance sensor units, a reset coil and a compensation coil. The magnetoresistance sensor units are disposed on the substrate. The reset coil is disposed over the magnetoresistance sensor units for introducing a resetting current. A magnetic filed generated from the reset current is used for resetting magnetization directions of the magnetoresistance sensor units. The reset coil includes a plurality of first main segments. The compensation coil is disposed over the magnetoresistance sensor units for introducing a compensating current. Another magnetic filed generated from the compensating current is used as a compensation magnetic field applied on the magnetoresistance sensor units. The compensation coil includes a plurality of second main segments. The first main segments of the reset coil are perpendicular to the second main segments of the second coil.

According to an embodiment of the invention, the reset coil further includes a plurality of connection segments. The first main segments are arranged in parallel and spaced apart from each other, each of the connection segments is connected between terminals on two of the first main segments that are adjacent to one another. The first main segments and the connection segments of the reset coil are connected to form a spiral-shaped reset coil.

According to an embodiment of the invention, the first main segments are allocated to be perpendicular to the magnetoresistance sensor units.

According to an embodiment of the invention, the reset coil includes a plurality of notch structures located at turning portions of the reset coil.

According to an embodiment of the invention, the compensation coil further includes a plurality of connection segments. The second main segments are arranged in parallel and spaced apart from each other, each of the connection segments is connected between terminals on two of the second main segments that are adjacent to one another. The second main segments and the connection segments of the compensation coil are connected to form a first spiral portion and a second spiral portion.

According to an embodiment of the invention, the second main segments are allocated in parallel with the magnetoresistance sensor units.

According to an embodiment of the invention, at least parts of the second main segments cover the magnetoresistance sensor units.

According to an embodiment of the invention, the compensating current has an identical current direction upon aforesaid parts of the second main segments when the compensating current flows through aforesaid parts of the second main segments.

According to an embodiment of the invention, each of the magnetoresistance sensor units is formed in a bar shape. Each of two terminals of each of the magnetoresistance sensor units is formed in a pointed shape with acute angles.

According to an embodiment of the invention, the magnetic sensor apparatus is an anisotropic magnetoresistance (AMR) sensor apparatus, and each of the magnetoresistance sensor units includes an anisotropic magnetoresistance material.

### BRIEF DESCRIPTION OF THE DRAWINGS

The invention can be more fully understood by reading the following detailed description of the embodiment, with reference made to the accompanying drawings as follows:

FIG. 1 is a top view illustrating a magnetic sensor apparatus according to an embodiment of the disclosure;

FIG. 2 is a schematic diagram illustrating magnetoresistance sensor units shown in FIG. 1;

FIG. 3 is a schematic diagram illustrating a compensation coil shown in FIG. 1;

FIG. 4 is a schematic diagram illustrating the compensation coil shown in FIG. 1;

FIG. 5 is a schematic diagram illustrating a reset coil shown in FIG. 1; and

FIG. 6 is a schematic diagram illustrating the reset coil shown in FIG. 1; and

FIG. 7 is a schematic diagram illustrating both of the compensation coil and the reset coil according to an embodiment of the disclosure.

### DETAILED DESCRIPTION

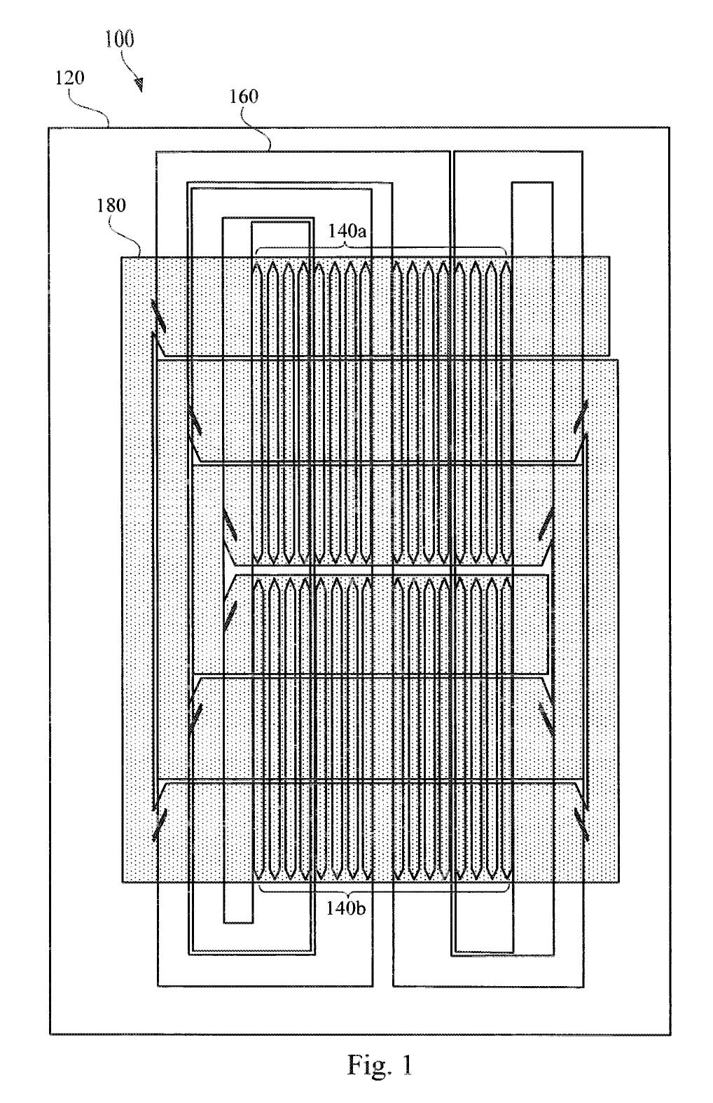

Reference is made to FIG. 1, which is a top view illustrating a magnetic sensor apparatus 100 according to an embodiment of the disclosure. As shown in FIG. 1, the magnetic sensor apparatus 100 at least includes a substrate 120, a plurality of magnetoresistance sensor units 140a and 140b, a compensation coil 160 and a reset coil 180.

In practical applications, the magnetic sensor apparatus 100 may further include input/output interface terminals (not shown) and corresponding connection wirings (not shown) for introducing current or voltage signals which are used for the magnetoresistance sensor units 140a and 140b, the compensation coil 160 and the reset coil 180, as will be described below. The implementations of input/output interface terminals and connection wirings are well known by persons skilled in the art and therefore will not be described in detail.

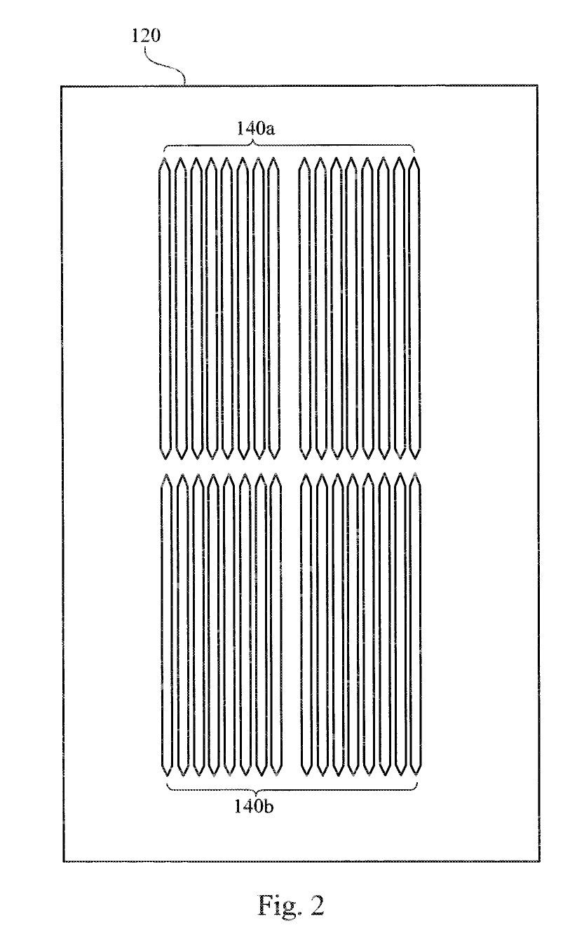

Reference is made to FIG. 2, which is a schematic diagram ustrating the magnetoresistance sensor units 140a and 140b shown in FIG. 1. As shown in FIG. 1 and FIG. 2, the magnetic sensor apparatus 100 includes several magnetoresistance sensor units 140a and 140b each disposed on the substrate 120. In this embodiment, the magnetic sensor apparatus 100 includes sixteen magnetoresistance sensor units 140a and sixteen magnetoresistance sensor units 140b, but the invention is not limited to a specific number of magnetoresistance sensor units. In practical applications, the number of magnetoresistance sensor units is determined by actual requirements (e.g., sensing area of the magnetic sensor apparatus 100). As shown in FIG. 2, each of the magnetoresistance sensor units 140a and 140b is formed in a bar shape. Each of two terminals of each magnetoresistance sensor units 140a and 140b is formed in a pointed shape with acute angles. That is, if we view the magnetoresistance sensor units 140a and 140b in FIG. 2 as if they are shown in cross section, each of the magnetoresistance sensors 140a and 140b has a straight-bar portion and two terminals respectively at opposite ends of the straight-bar portion. Moreover, each of the terminals of each of the magnetoresistance sensors 140a and 140b is angled to form two interior angles with the straight-bar portion, and each interior angle is less than 90 degrees.

Terminals of a traditional magnetoresistance sensor unit are usually formed in a square shape. In the traditional design, the linear top edge on the upper terminal or the linear bottom edge on the lower terminal of the square-shaped magnetoresistance sensor unit will be polarized easily, such that static magnetic fields will be formed on the terminals. Such static magnetic fields will reduce the sensitivity in magnetic sensing of the traditional magnetoresistance sensor units. In the embodiment of this invention, however, the terminals of the magnetoresistance sensor units 140a and 140b are formed in pointed shapes with acute angles in the manner described above, such that the polarization effect on the outer lines of the terminals can be reduced and the static magnetic fields can be prevented.

In the embodiment, the magnetic sensor apparatus 100 can be an anisotropic magnetoresistance (AMR) sensor apparatus. Each of the magnetoresistance sensor units 140a and 140b may include an anisotropic magnetoresistance material. The resistance of the magnetoresistance sensor units 140a and 140b is varied according to a magnetic field applied thereon. Therefore, the magnetic sensor apparatus 100 may utilize the magnetoresistance sensor units 140a and 140b to sense a surrounding magnetic field.

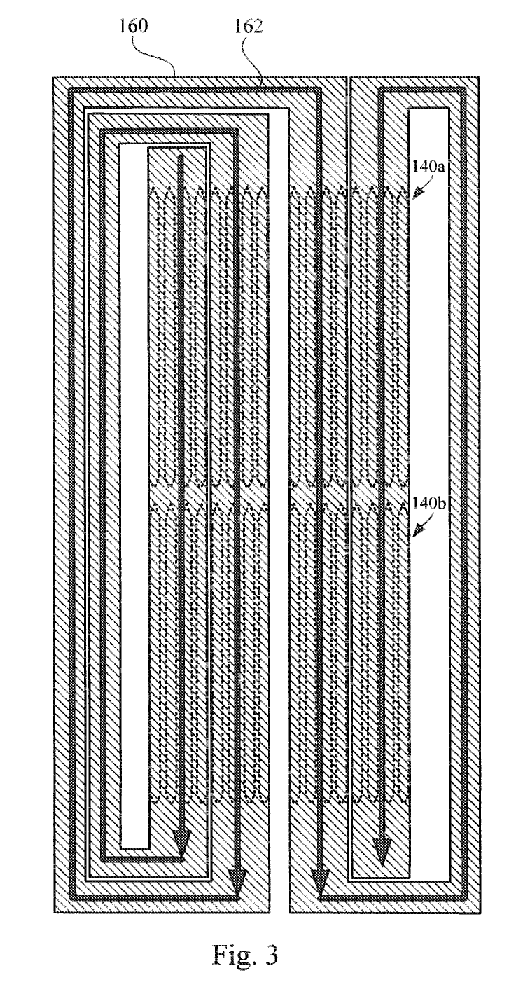

Reference is made to FIG. 3. FIG. 3 is a schematic diagram illustrating the compensation coil 160 shown in FIG. 1. As shown in FIG. 1 and FIG. 3, the compensation coil 160 is disposed over the magnetoresistance sensor units 140a and 140b. At least part of the compensation coil 160 covers the magnetoresistance sensor units 140a and 140b. The compensation coil 160 is used for introducing a compensation current 162 (shown by the bold arrow in FIG. 3). The compensation current 162 flows through the compensation coil 160 for establishing a compensation magnetic field that is used for the magnetoresistance sensor units 140a and 140b. That is, the compensation magnetic field is used for calibrating the magnetic sensitivity of the magnetoresistance sensor units 140a and 140b which may be changed due to the environmental temperature. The degree of calibration can be adjusted by controlling the current value of the compensation current 162.

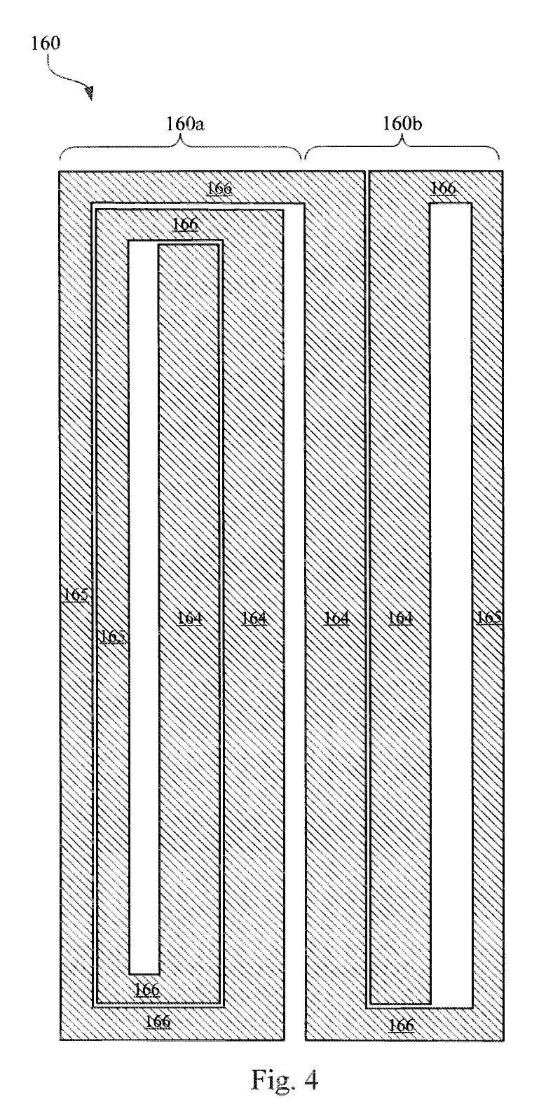

Reference is made to FIG. 4 at the same time. FIG. 4 is a schematic diagram illustrating the compensation coil 160 shown in FIG. 1. The compensation coil of the embodiment shown in FIG. 4 includes a first spiral portion 160a and a second spiral portion 160b in opposite directions.

As shown in FIG. 4, the compensation coil 160 includes a plurality of main segments 164 and 165 and a plurality of connection segments 166. The main segments 164 and 165 are arranged in parallel and spaced apart from each other. Each of the connection segments 166 is connected between terminals on two of the main segments 164 and 165 that are adjacent to one another. The main segments 164 and 165 and the connection segments 166 of the compensation coil 166 are connected to form the first spiral portion 160a and the second spiral portion 160b.

As shown in FIG. 3 and FIG. 4, the main segments 164 and 165 are allocated in parallel with the magnetoresistance sensor units 140a and 140b. The connection segments 166 are allocated to be perpendicular to the magnetoresistance sensor units 140a and 140b.

As shown in FIG. 3 and FIG. 4, there are parts of the main segments (i.e., the main segments 164 in FIG. 4) among the main segments 164 and 165 covering or overlapping) over the magnetoresistance sensor units 140a and 140b.

When the compensating current 162 flows through aforesaid parts of the main segments 164, the compensating current 162 has an identical current direction upon aforesaid parts of the main segments 164.

It is noted that the compensation coil 160 in the embodiment has a double-spiral structure. In the embodiment, the first spiral portion 160a on the left side of the compensation coil 160 can be formed using a clockwise spiral, while the second spiral portion 160b on the right side of the compensation coil 160 can be formed using a counter-clockwise spiral, but the invention is not limited to this. In another embodiment, the spiral directions of the first spiral portion 160a and the second spiral portion 160b can be alternated. The magnetoresistance sensor units 140a and 140b can be located at specific positions relative to the compensation coil 160, as shown in FIG. 3, such that the compensation current 162 flows over the space above all of the magnetoresistance sensor units 140a and 140b in the same direction. In the embodiment shown in FIG. 3, the compensation current 162 flows upward over the space above all of the magnetoresistance sensor units 140a and 140b. Therefore, the compensation current 162 may establish a compensation magnetic field in the same direction for all of the magnetoresistance sensor units 140a and 140b. Furthermore, the compensation coil 160 with double spirals in opposite directions may reduce the coil width and the overall coil area of the magnetic sensor apparatus 100, such that the area efficiency of the magnetic sensor apparatus 100 can be elevated.

It is noted that the compensation current 162 flows upward over the space above all of the magnetoresistance sensor units 140a and 140b in the embodiment, but the invention is not limited in this regard. The same effect can be achieved by an opposite direction for the compensation current 162. The direction of the compensation current 162 can be determined by the direction of the magnetic field to be compensated, e.g., determined by a magnetic field in the surrounding area.

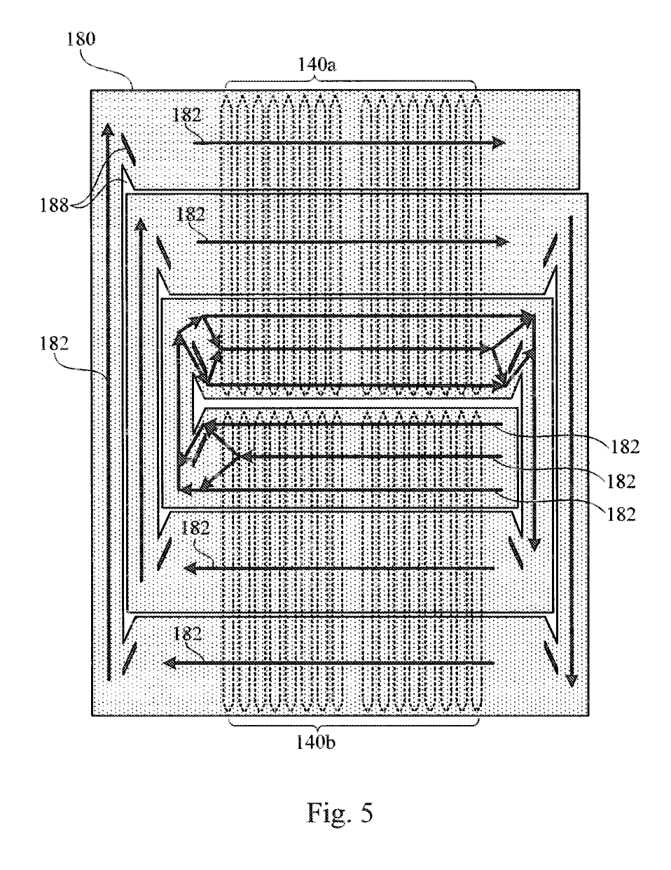

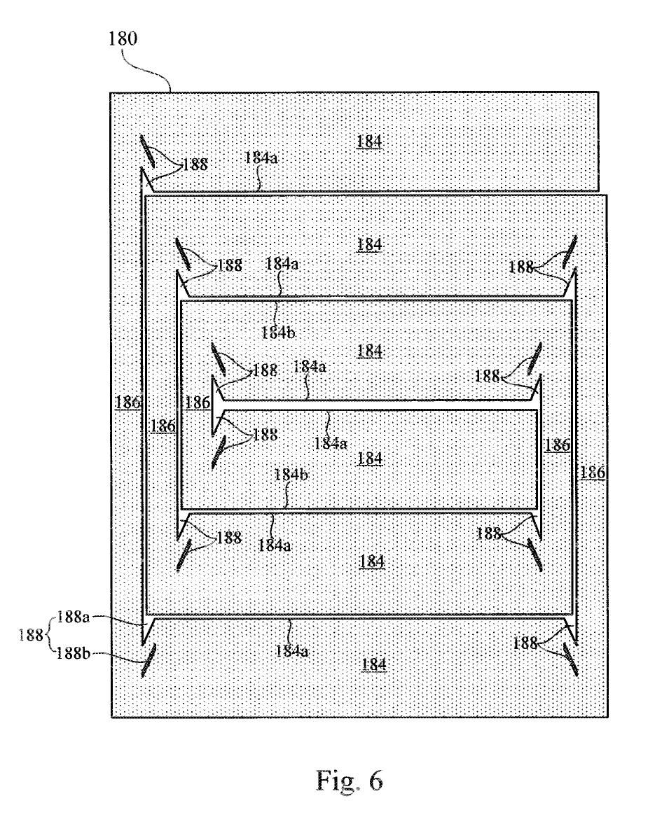

Reference is made to FIG. 5 and FIG. 6, which are schematic diagrams illustrating the reset coil 180 shown in FIG. 1. As shown in FIG. 5, the reset coil 180 is used for introducing a resetting current 182. At least part of the reset coil 180 covers the magnetoresistance sensor units 140a and 140b. The resetting current 182 is used for resetting the magnetoresistance sensor units 140a and 140b.

As shown in FIG. 6, the reset coil 180 includes several main segments 184 and several connection segments 186. The main segments 184 are arranged in parallel and spaced apart from each other. Each of the connection segments 186 is connected between terminals of two adjacent main segments 184, such that the main segments 184 and the connection segments 186 of the reset coil 180 are connected to form a spiral-shaped reset coil 180. The reset coil 180 can be a spiral formed in a clockwise direction or a counter-clockwise direction. In the embodiment, the reset coil 180 is shown by way of example as being formed as a spiral in the clockwise direction, but the invention is not limited in this regard.

Based on the characteristic of the magnetoresistance material, each of the magnetoresistance sensor units 140a and 140b may include several magnetic zones. Each magnetic zone has a magnetization direction. As shown in FIG. 5, the resetting current 182 flows through the reset coil 180 from left to right at areas corresponding to the eight magnetoresistance sensor units 140a in the top portion of the magnetic sensor apparatus 100. The resetting current 182 establishes a resetting magnetic field for resetting the magnetization direction of every magnetic zone in the magnetoresistance sensor units 140a, such that the magnetic zones in the magnetoresistance sensor units 140a are reset (magnetized) to have an identical magnetization direction.

On the other hand, again referring to FIG. 5, the resetting current 182 flows through the reset coil 180 from right to left at areas corresponding to the eight magnetoresistance sensor units 140b in the bottom portion of the magnetic sensor apparatus 100. The resetting current 182 establishes another resetting magnetic field for resetting the magnetization direction of every magnetic zone in the magnetoresistance sensor units 140b, such that the magnetic zones in the magnetoresistance sensor units 140b are reset (magnetized) to have another identical magnetization direction, that is, a magnetization direction different from the magnetization direction of the magnetoresistance sensor units 140a.

In this way, the magnetoresistance sensor units 140a may have an identical magnetization direction after the resetting procedure, and the magnetoresistance sensor units 140b may have an identical magnetization direction, which is different from that of the magnetoresistance sensor units 140a, after the resetting procedure. The resetting procedure can be performed each time before a sensing process or it may be performed periodically, so as to ensure that the magnetoresistance sensor units 140a have the same magnetization direction and the magnetoresistance sensor units 140b have the same magnetization direction. In this way, the sensing accuracy can be ensured in the magnetic sensor apparatus 100. Furthermore, the distortion due to different temperatures can be calibrated according to a comparison result between two sensing outcomes generated under two reset magnetic fields in opposite directions. In other words, the current value of the compensation current 162 can be determined by aforesaid comparison result between two sensing outcomes corresponding to two reset magnetic fields in opposite directions, and this may be particularly beneficial for some compass systems or precise devices demanding high sensitivity.

Furthermore, as shown in FIG. 5 and FIG. 6, a coil width of the main segments 184 of the reset coil 180 is larger than a coil width of the connection segments 186.

During actual use, the resetting current 182 tends to travel along the shortest flowing pattern. In a traditional spiral-shaped resetting coil, most of the resetting current travels along the inner edges (i.e., the edges closer to the center of the spiral than outer edges thereof) on the main segments of the resetting coil. Therefore, the resetting current can not be distributed evenly to every part of the spiral-shaped resetting coil. The resetting current may be concentrated at the inner edges on the main segments of the resetting coil instead. Such uneven distribution of the resetting current is more severe when the main segments 184 are wide.

Therefore, in some embodiments of the invention, there are several notch structures 188 formed in the reset coil 180. The notch structures 188 are located at turning portions of the reset coil 180. As shown in FIG. 6, each of the main segments 184 has an inner edge 184a closer to a center of the spiral-shaped reset coil 180 than an opposite outer edge 184b of the main segment 184. The notch structures 188 are formed extending from and adjacent to the inner edges 184a of the main segments 184, as will be described in greater detail below.

As shown in FIG. 6, each of the notch structures 188 includes a cone-shaped concave 188a, and a slit 188b in close proximity to the cone-shaped concave 188a. The extending direction of the slit 188b can be parallel with one side of the cone-shaped concave 188a. In the embodiment, while each of the notch structures 188 is described as including the cone-shaped concave 188a and the slit 188b, the invention is not limited in this regard. In another embodiment, each of the notch structures 188 may include a cone-shaped concave on the inner edge of the reset coil, or any equivalent concave/slit/notch in different shapes around the inner edge.

Referring both to FIG. 5 and FIG. 6, the design of the notch structures 188 can be used to prevent the resetting current from concentrating at the inner edges 184a of the main segments 184. When the resetting current 182 flows through the turning portions of the reset coil 180, the cone-shaped concaves 188a and the slits 188b are designed for re-distributing the flowing pattern of the resetting current 182 to every part of the reset coils 180. As shown in FIG. 5, the flowing pattern of the resetting current 182 is re-distributed to the inner side, the middle and the outer side on the reset coil 180. In order to facilitate understanding in FIG. 5, only the flowing pattern on the innermost ring of the reset coil 180 is shown. However, in actual application, the same effect may be realized around the notch structures 188 on every turning portion of the reset coil 180.

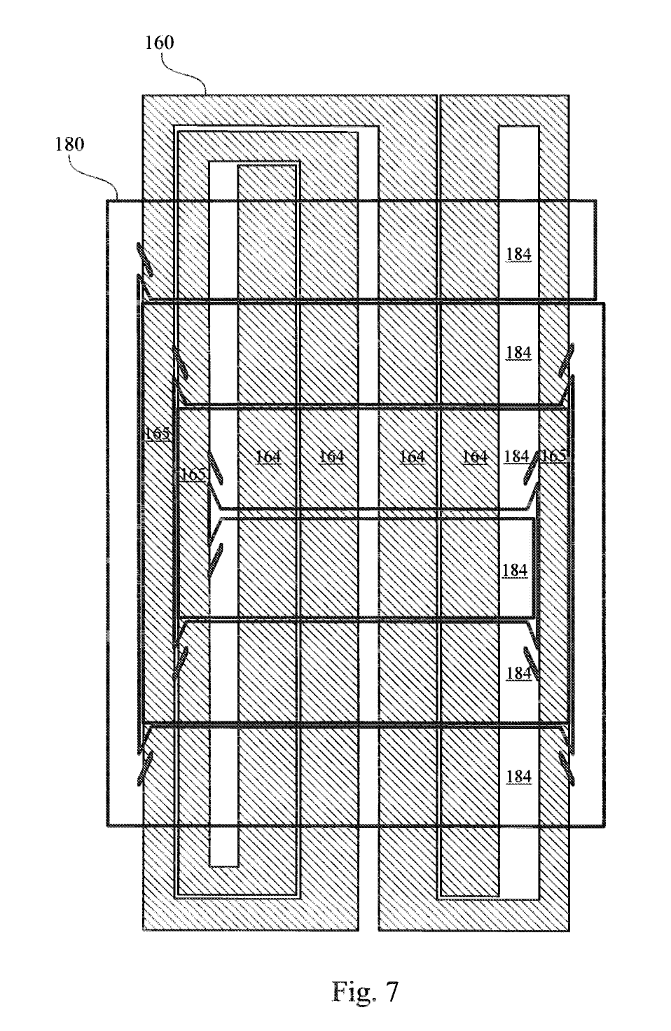

It is noted that, the magnetic sensor apparatus 100 includes the compensation coil 160 and the reset coil 180 at the same time. Reference is made to FIG. 7, which is a schematic diagram illustrating both of the compensation coil 160 and the reset coil 180 according to an embodiment of the disclosure. As shown in FIG. 7, the main segments 164 and 165 of the compensation coil 160 are perpendicular to the main segments 184 of the reset coil 180

In the embodiment illustrated in FIG. 4, FIG. 6 and FIG. 7, the main segments 184 of the reset coil 180 are allocated to be perpendicular to the magnetoresistance sensor units 120. The main segments 164 and 165 of the compensation coil 160 are allocated in parallel with the magnetoresistance sensor units 120. Therefore, each of the reset coil 180 and the compensation coil 160 can be used to generate a magnetic field for different purpose, so as to reset or compensate the magnetoresistance sensor units 120.

In practical applications, each of the magnetoresistance sensor units 140a and 140b, the compensation coil 160 and the reset coil 180 can be formed by a film structure disposed on the substrate 120. The vertical sequence of aforesaid components mentioned in embodiments above is only for demonstration. The magnetoresistance sensor units 140a and 140b, the compensation coil 160 and the reset coil 180 are not limited to a specific vertical sequence in the invention.

In summary, this disclosure provides a magnetic sensor apparatus including a plurality of magnetoresistance sensor units, a compensation coil and a reset coil. The compensation coil is used for introducing a compensation current for establishing a compensation magnetic field that is used for calibrating the magnetic sensitivity of the magnetoresistance sensor units which may be changed due to different temperatures. The reset coil is used for introducing a resetting current for establishing a resetting magnetic field, so as to reset the magnetization directions of the magnetoresistance sensor units to the same direction at the beginning of the magnetic sensing process. Furthermore, the distortion due to different temperatures can be calibrated according to a comparison result between two sensing outcomes generated under two reset magnetic fields in opposite directions. In other words, the current value of the compensation current can be determined by aforesaid comparison result between two sensing outcomes corresponding to two reset magnetic fields in opposite directions. The main segments of the reset coil and the main segment of the compensation coil are perpendicular to each others, and the reset coil and the compensation coil are used for establishing two magnetic fields for different purposes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A magnetic sensor apparatus, comprising:
a substrate;
a plurality of magnetoresistance sensor units disposed on the substrate;
a reset coil disposed over the magnetoresistance sensor units for introducing a resetting current, a magnetic filed generated from the reset current being used for resetting magnetization directions of the magnetoresistance sensor units, the reset coil comprising a plurality of first main segments; and
a compensation coil disposed over the magnetoresistance sensor units for introducing a compensating current, another magnetic filed generated from the compensating current being used as a is compensation magnetic field applied on the magnetoresistance sensor units, the compensation coil comprising a plurality of second main segments, the first main segments of the reset coil being perpendicular to the second main segments of the second coil.

2. The magnetic sensor apparatus of claim 1, wherein the reset coil further comprises a plurality of connection segments, the first main segments are arranged in parallel and spaced apart from each other, each of the connection segments is connected between terminals on two of the first main segments that are adjacent to one another, and the first main segments and the connection segments of the reset coil are connected to form a spiral-shaped reset coil.

3. The magnetic sensor apparatus of claim 2, wherein the first main segments are allocated to be perpendicular to the magnetoresistance sensor units.

4. The magnetic sensor apparatus of claim 1, wherein the reset coil comprises a plurality of notch structures located at turning portions of the reset coil.

5. The magnetic sensor apparatus of claim 1, wherein the compensation coil further comprises a plurality of connection segments, the second main segments are arranged in parallel and spaced apart from each other, each of the connection segments is connected between terminals on two of the second main segments that are adjacent to one another, and the second main segments and the connection segments of the compensation coil are connected to form a first spiral portion and a second spiral portion.

6. The magnetic sensor apparatus of claim 5, wherein the second main segments are allocated in parallel with the magnetoresistance sensor units.

7. The magnetic sensor apparatus of claim 5, wherein at least parts of the second main segments cover the magnetoresistance sensor units.

8. The magnetic sensor apparatus of claim 7, wherein the compensating current has an identical current direction upon aforesaid parts of the second main segments when the compensating current flows through aforesaid parts of the second main segments.

9. The magnetic sensor apparatus of claim 1, wherein each of the magnetoresistance sensor units is formed in a bar shape, and each of two terminals of each of the magnetoresistance sensor units is formed in a pointed shape with acute angles.

10. The magnetic sensor apparatus of claim 1, wherein the magnetic sensor apparatus is an anisotropic magnetoresistance (AMR) sensor apparatus, and each of the magnetoresistance sensor units comprises an anisotropic magnetoresistance material.
